(19) United States
(12) Patent Application Publication
(10) Pub. No.: US 2026/0123262 A1
(43) Pub. Date: Apr. 30, 2026

(54) DISPLAY PANEL AND DISPLAY APPARATUS

(71) Applicant: HKC CORPORATION LIMITED, SHENZHEN (CN)

(72) Inventors: Yao LI, SHENZHEN (CN); Lidan YE, SHENZHEN (CN)

(73) Assignee: HKC CORPORATION LIMITED, SHENZHEN (CN)

(21) Appl. No.: 19/369,366

(22) Filed: Oct. 27, 2025

(30) Foreign Application Priority Data
Oct. 31, 2024 (CN) 202411548952.7

(51) Int. Cl. H10K 59/80; H10K 59/122; H10K 59/123

(52) U.S. Cl. CPC H10K 59/8794; H10K 59/122; H10K 59/123

(57) ABSTRACT

A display panel and a display apparatus are provided and include: a driving substrate, including a driving circuit layer and driving electrodes electrically which are connected; a light-emitting support plate, including: a glass substrate, arranged on the driving substrate and having electrode through-holes, each electrode through-hole corresponding to one corresponding driving electrode; and light-emitting units, arranged in an array and on a side of the glass substrate away from the driving substrate, each light-emitting unit being electrically connected to one corresponding driving electrode through one corresponding electrode through-hole; the light-emitting support plate includes heating assemblies, and each heating assembly is arranged between adjacent two light-emitting units; the glass substrate defines heating through-holes, each heating assembly is electrically connected to the driving circuit layer through one corresponding heating through-hole. When temperatures of the light-emitting units are lower than a threshold temperature, the heating assemblies are activated to heat the light-emitting units.

### CROSS REFERENCE TO RELATED APPLICATIONS

The present disclosure claims foreign priority to Chinese Patent Application No. 202411548952.7, filed on October 31, 2024, the contents of which are hereby incorporated by reference in its entirety.

### TECHNICAL FIELD

The present disclosure relates to the field of display technologies, in particular to a display panel and a display apparatus.

### BACKGROUND

A single-crystal silicon driving backplane is a driving substrate formed by a semiconductor device serving as a driving unit, and the semiconductor device is manufactured through a Complementary Metal-Oxide-Semiconductor (CMOS) process. Compared to a conventional Active-Matrix Organic Light-Emitting Diode (AMOLED) panel using amorphous silicon thin-film transistors, microcrystalline silicon thin-film transistors, or low-temperature polycrystalline silicon thin-film transistors as a backplane, a single-crystal silicon driving backplane has higher carrier mobility. Therefore, a silicon-based OLED display panel is the highest-performing display panel type currently for Augmented Reality (AR)/Virtual Reality (VR) field products.

Currently, the silicon-based OLED display panel integrates traditionally externally bonded display chips into the silicon-based driving backplane. The manufacturing process involves evaporating OLED light-emitting devices on the silicon-based driving substrate. Specifically, an anode is first deposited, followed by the manufacture of a pixel definition layer, and then the sequential deposition of an organic light-emitting layer and a cathode. This process may manufacture a smaller pixel unit, achieving display fineness beyond retinal resolution, with advantages such as high resolution, high integration, low power consumption, small size, and lightweight. Additionally, the silicon-based driving substrate in the silicon-based OLED display panel may operate at a low temperature and is not easily affected by a low temperature.

However, the light-emitting property and temperature sensitivity of an OLED light-emitting material causes the light-emitting efficiency to significantly decrease at a low temperature, leading to a sharp decrease in brightness and resulting in display abnormality and low light-emitting efficiency for the entire composite structure.

### SUMMARY

A first solution of the present disclosure is to provide a display panel. The display panel includes: a driving substrate, including a driving circuit layer and a plurality of driving electrodes electrically connected to the driving circuit layer; a light-emitting support plate, including: a glass substrate, arranged on the driving substrate and having a plurality of electrode through-holes, and each of the plurality of electrode through-holes corresponding to one corresponding driving electrode of the plurality of driving electrodes; and light-emitting units, arranged in an array and on a side of the glass substrate away from the driving substrate, each of the light-emitting units being electrically connected to one corresponding driving electrode of the plurality of driving electrodes through one corresponding electrode through-hole of the plurality of electrode through-holes; the light-emitting support plate includes heating assemblies, and each of the heating assemblies is arranged between adjacent two light-emitting units of the light-emitting units; the glass substrate defines heating through-holes, and each of the heating assemblies is electrically connected to the driving circuit layer through one corresponding heating through-hole of the heating through-holes. When temperatures of the light-emitting units are lower than a threshold temperature, the heating assemblies are activated to heat the light-emitting units.

A second solution of the present disclosure is to provide a display apparatus. The display apparatus includes: a display panel mentioned above; and a control circuit board, electrically connected to the display panel and configured to control the display panel to display a corresponding image.

A third solution of the present disclosure is to provide a display panel. The display panel includes: a driving substrate, including a driving circuit layer and a plurality of driving electrodes electrically connected to the driving circuit layer; and a light-emitting support plate, including: a plurality of electrode through-holes, and each of the plurality of electrode through-holes corresponding to one corresponding driving electrode of the plurality of driving electrodes; and light-emitting units, arranged in an array and on a side of the light-emitting support plate, each of the light-emitting units being electrically connected to one corresponding driving electrode of the plurality of driving electrodes through one corresponding electrode through-hole of the plurality of electrode through-holes; the light-emitting support plate includes heating assemblies, and each of the heating assemblies is arranged between adjacent two light-emitting units of the light-emitting units; the light-emitting support plate defines heating through-holes, and each of the heating assemblies is electrically connected to the driving circuit layer through one corresponding heating through-hole of the heating through-holes; when temperatures of the light-emitting units are lower than a threshold temperature, the heating assemblies are activated to heat the light-emitting units.

### BRIEF DESCRIPTION OF THE DRAWINGS

To more clearly illustrate the technical solutions in the embodiments of the present disclosure, the accompanying drawings used in the embodiments will be briefly introduced below. It is obvious that the drawings in the following description are only some embodiments of the present disclosure. For those skilled in the art, other drawings may be obtained based on these drawings without creative work.

FIG. 1 is a structural schematic view of a first embodiment of a display panel according to the present disclosure.

FIG. 2 is a structural schematic view of a first embodiment of a heating assembly according to the present disclosure.

FIG. 3 is a structural schematic view of an electrode through-holes and a heating through-hole according to some embodiments of the present disclosure.

FIG. 4 is a structural schematic view of a second embodiment of a display panel according to the present disclosure.

FIG. 5 is a structural schematic view of a second embodiment of a heating assembly according to the present disclosure.

FIG. 6 is a structural schematic view of a third embodiment of a display panel according to the present disclosure.

FIG. 7 is a planar distribution schematic view of heating assemblies according to some embodiments of the present disclosure.

FIG. 8 is a structural schematic view of a display apparatus according to some embodiments of the present disclosure.

### DETAILED DESCRIPTIONS

The following describes the technical solutions of some embodiments of the present disclosure in detail with reference to the drawings.

In the following description, details such as system structures, interfaces, and technologies are provided for description only and not for limitation, to facilitate a thorough understanding of the present disclosure.

The technical solutions in embodiments of the present disclosure are clearly and completely described in conjunction with the drawings in the embodiments of the present disclosure. It is obvious that the described embodiments are only some embodiments of the present disclosure, and not all embodiments. All other embodiments acquired by those skilled in the art based on the embodiments in the present disclosure without the creative work are all within the scope of the present disclosure.

In the present disclosure, the terms “first,” “second,” and “third” are used for descriptive purposes only and should not be understood as indicating or implying relative importance or implicitly specifying the quantity of the indicated technical features. Thus, features defined by “first,” “second,” or “third” may explicitly or implicitly include at least one such feature. In the description of the present disclosure, “plurality” or “multiple” means at least two, such as two, three, etc., unless otherwise explicitly defined. Directional terms (e.g., upper, down, left, right, front, rear, etc.) in the embodiments of the present disclosure are only configured to explain the relative positional relationships or movements of components in a specific posture (as shown in the drawings). If the specific posture changes, the directional terms will change accordingly. In addition, the terms “include” and “have” and any variations thereof are intended to cover non-exclusive inclusion. For example, a process, a method, a system, a product, or a device that includes a series of operations or units is not limited to the listed operations or units, but optionally also includes operations or units not listed, or optionally includes other operations or units inherent to the process, the method, the product, or the device.

“Embodiment” mentioned in the present disclosure means that specific features, structures, or characteristics described in conjunction with embodiments may be included in at least one embodiment of the present disclosure. Some embodiments including a phrase appearing in various positions in the specification does not necessarily refer to the same embodiment, and are not independents or alternative embodiment that are mutually exclusive with other embodiments. Those skilled in the art explicitly and implicitly understand that the embodiments described in the present disclosure can be combined with other embodiments.

The present disclosure will be described in detail below with reference to the accompanying drawings and some embodiments.

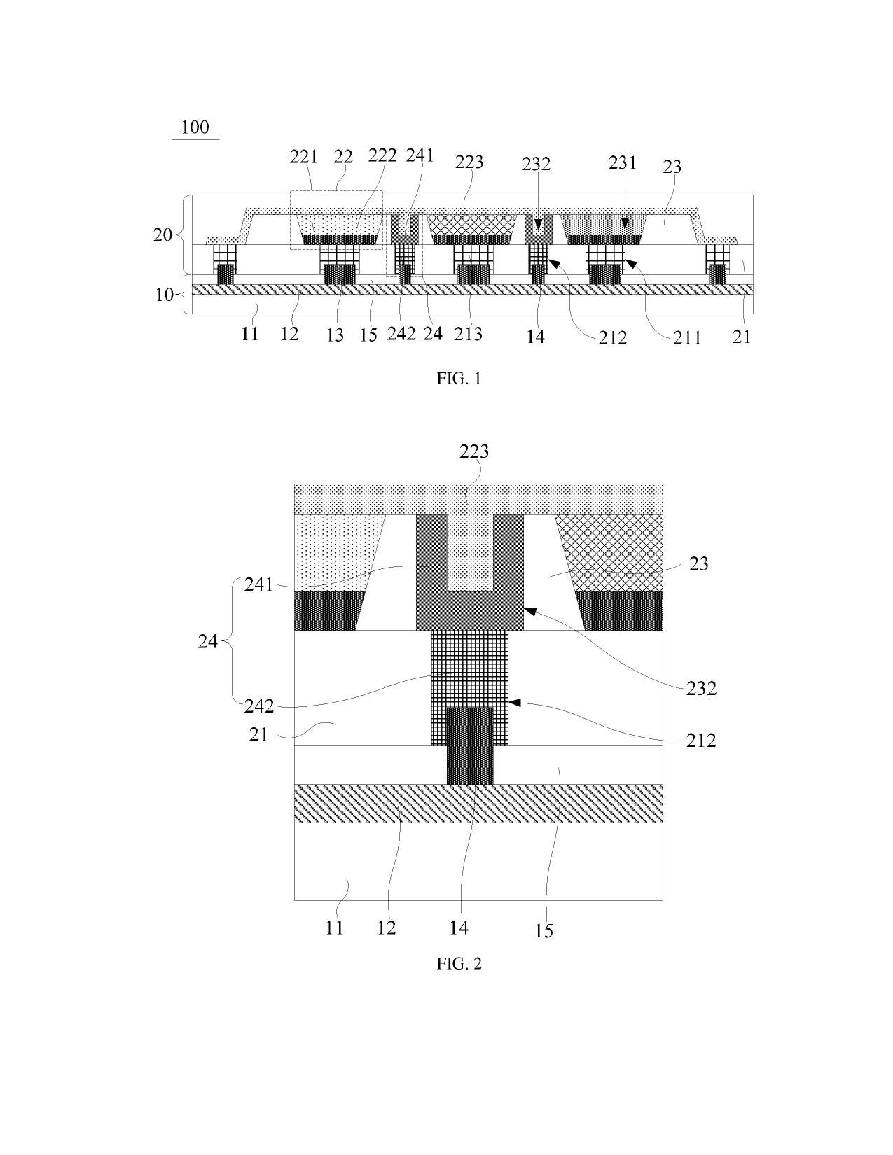

Please refer to FIG. 1, FIG. 1 is a structural schematic view of a first embodiment of a display panel according to the present disclosure. In this embodiment, a display panel 100 is provided. The display panel 100 may include a driving substrate 10 and a light-emitting support plate 20. The driving substrate 10 and the light-emitting support plate 20 are arranged opposite to each other and are electrically connected to drive the light-emitting support plate to display an image.

The driving substrate 10 may include a driving circuit layer 12 and a plurality of driving electrodes 13 electrically connected to the driving circuit layer 12. The driving circuit layer 12 may include a plurality of pixel driving circuits (not shown), each of the pixel driving circuits may include a semiconductor driving device. In some embodiments, a CMOS device may serve as the semiconductor driving device to form a pixel driving circuit, thereby driving the light-emitting support plate 20 to emit light. Each of the plurality of driving electrodes 13 is connected to a corresponding pixel driving circuit and a corresponding power signal to transmit a corresponding driving signal to the light-emitting support plate 20.

In some embodiments, the driving substrate 10 may include a silicon-based substrate 11 and an insulating protective layer 15. The silicon-based substrate 11 is configured to carry the driving circuit layer 12, the driving electrodes 13, the insulating protective layer 15, and other film layers. In some embodiments, the silicon-based substrate 11 may be configured as a single-crystal silicon substrate. The insulating protective layer 15 is arranged on a side of the driving circuit layer 12 away from the silicon-based substrate 11 and may define a plurality of openings, and each of the plurality of openings corresponds to one driving electrode 13 to expose each driving electrode 13. That is, the orthographic projection of each of the openings of the insulating protective layer 15 on the driving circuit layer 12 overlap with a orthographic projection of one corresponding driving electrode 13 on the driving circuit layer 12, so that the each of the openings directly faces the corresponding driving electrode 13 to expose the corresponding driving electrode 13.

The light-emitting support plate 20 may include a glass substrate 21 and light-emitting units 22 arranged on a side of the glass substrate 21 away from the driving substrate 10. The glass substrate 21 is arranged on the driving substrate 10 and may include a plurality of electrode through-holes 211, and each of the plurality of electrode through-holes 211 corresponds to one driving electrode 13, enabling each of the light-emitting units 22 to be electrically connected to one corresponding driving electrode 13 through the corresponding electrode through-hole 211. In some embodiments, each of the electrode through-holes 211 may be filled with a conductive portion 213. The opposite sides of the conductive portion 213 are respectively electrically connected to one corresponding light-emitting unit 22 and one driving electrode 13 in the thickness direction of the glass substrate 21, thereby achieving a driving signal connection. The light-emitting units 22 are arranged in an array and on the side of the glass substrate 21 away from the driving substrate 10, and the orthographic projection of each of the light-emitting units 22 on the glass substrate 21 covers one corresponding conductive portion 213 to touch the corresponding conductive portions 213 and forming an electrical connection with the corresponding conductive portion 213. In some embodiments, each of the electrode through-holes 211 may be circular, rectangular, polygonal, or elliptical, etc. In the thickness direction of the glass substrate 21, each of the electrode through-holes 211 may be tapered, straight, or double-flared holes with one small center and two large sides, which is depended on actual needs.

With the above arrangements, the glass substrate 21 is arranged between the driving substrate 10 and the light-emitting units 22. The light-emitting units 22 are manufactured on the glass substrate 21, and the glass substrate 21 protects the driving circuit layer 12 on the driving substrate 10 during the manufacture process of the light-emitting units 22, avoiding damage or adverse effect on the driving circuit layer 12 caused by directly manufacturing the light-emitting units 22 on the driving substrate 10, thereby improving product yield. By defining the electrode through-holes 211 in the glass substrate 21 and filling each of the electrode through-holes 211 with the corresponding conductive portion 213, the light-emitting units 22 may be electrically connected to the driving substrate 10 through the corresponding conductive portion 213 for signal transmission, thereby achieving image display.

Moreover, the glass substrate 21 serving as the substrate for the light-emitting support plate 20 provides better insulation performance compared to the silicon-based substrate 11. Therefore, the wall of each of the electrode through-holes 211 in the glass substrate 21 does not require an additional insulating oxide layer, nor specialized thin-wafer handling techniques, reducing costs. Additionally, the glass substrate 21 is less expensive than the silicon substrate, further reducing costs. Moreover, the excellent insulation of the glass substrate 21 may not easy to generate electromagnetic coupling effects during signal transmission, effectively reducing the problems such as signal insertion loss and crosstalk, etc., thereby ensuring signal integrity. Furthermore, manufacturing the light-emitting units 22 on the glass substrate 21 facilitates the implementation of the large-sized light-emitting support plate 20. By arranging the light-emitting units 22 on the glass substrate 21 to form the light-emitting support plate 20, the driving substrate 10 and the light-emitting support plate 20 may be manufactured separately, shortening a manufacture duration and improving a production cycle.

Each light-emitting unit 22 may include an anode electrode 221, a light-emitting layer 222, and a cathode electrode 223 sequentially stacked in the thickness direction of the glass substrate 21 away from the glass substrate 21. The orthographic projection of the anode electrode 221 on the glass substrate 21 covers one corresponding electrode through-hole 211 to touch one corresponding conductive portion 213 and form an electrical connection with the corresponding conductive portion 213. The cathode electrode 223 of each of the light-emitting units 22 is connected to each other, and electrically connected to one corresponding driving electrode 13 on the driving substrate 10 through one corresponding electrode through-hole at the edge of the glass substrate 21, such as through one corresponding conductive portion 213 in the corresponding electrode through-hole. In some embodiments, the light-emitting units 22 may include first, second, and third light-emitting units 22 emitting different colors, such as red, green, and blue light-emitting units 22, respectively, to achieve color display. In some embodiments, the light-emitting color of each light-emitting unit 22 is determined by the light-emitting color of the light-emitting layer 222. In other embodiments, the light-emitting units 22 may emit the same color, such as white, red, green, blue, or other colors, depending on actual needs. For example, the light-emitting units 22 emit white light, grayscale display may be achieved by controlling the brightness of the light-emitting units 22, and a color resist layer may be arranged above the light-emitting units 22 to achieve color display. The light-emitting units 22 may be current-driven light-emitting devices, such as one or more of Organic Light-Emitting Diodes (OLEDs), LEDs, Mini-LEDs, or Micro-LEDs. In this embodiment, the light-emitting units 22 being OLEDs are taken as an example.

Due to the temperature sensitivity of the light-emitting materials of the OLED light-emitting layers 222, the light-emitting efficiency significantly decreases at a low temperature, leading to a sharp decrease in brightness and resulting in display abnormality and low light-emitting efficiency. To solve the problems, the light-emitting support plate 20 in this embodiment may include heating assemblies 24, and each of the heating assemblies 24 is arranged between adjacent two light-emitting units 22. The glass substrate 21 may include heating through-holes 212, each of the heating assemblies 24 is electrically connected to the driving circuit layer 12 through one corresponding heating through-hole 212 for signal transmission. This allows the heating assemblies 24 to heat the light-emitting units 22 at a low temperature, raising temperatures of the light-emitting units 22 and reducing the decrease of light-emitting efficiency of the light-emitting units 22 at a low temperature.

In some embodiments, when the temperatures of the light-emitting units 22 fall are lower than a threshold temperature, the heating assemblies 24 are activated to heat the light-emitting units 22. In some embodiments, the threshold temperature may be a temperature at which the light-emitting efficiency of the light-emitting units 22 decreases by a%, where a% ranges from 0 to 40%. For example, a% is 20%, when the light-emitting efficiency of the light-emitting units 22 decreases by 20%, i.e., the light-emitting efficiency of the light-emitting units 22 decreases to 80% of original light-emitting efficiency, the temperature at this time is the threshold temperature. When the temperatures of the light-emitting units 22 are lower than the threshold temperature, the heating assemblies 24 are activated to heat the light-emitting units 22. When the temperatures rise to or are higher than the threshold temperature, the heating assemblies 24 are deactivated, that is, the heating assemblies 24 stop heating. This configuration reduces the impact of a low temperature on the light-emitting efficiency of the OLED light-emitting units 22, reducing the decrease of light-emitting efficiency of the light-emitting units 22 at a low temperature, thereby reducing the problem of brightness decrease and display abnormality of the display panel 100 at a low temperature.

Please continue to refer to FIG. 1. In this embodiment, the light-emitting support plate 20 may include a pixel definition layer 23 arranged on the glass substrate 21. The pixel definition layer 23 has a plurality of pixel openings 231, and each of the pixel openings 231 corresponds to one light-emitting unit 22. The anode electrodes 221, the light-emitting layers 222, and the cathode electrodes 223 are sequentially stacked in the corresponding pixel opening 231 along the direction of the glass substrate 21 away from the driving substrate 10 to form one corresponding light-emitting unit 22. The pixel definition layer 23 is configured to separate the anode electrodes 221 of different light-emitting units 22 and are configured to separate the light-emitting layers 222 of different light-emitting units 22, preventing color mixing between different light-emitting units 22.

The pixel definition layer 23 may include heating openings 232, and each of the heating openings 232 is located between adjacent two pixel openings 231. The orthographic projection of each of the heating openings 232 on the glass substrate 21 covers one corresponding heating through-hole 212, that is, each of the heating openings 232 is connected to the corresponding heating through-hole 212. Each of the heating assemblies 24 is arranged in one corresponding heating opening 232 and one corresponding heating through-hole 212, a side of each of the heating assemblies 24 close to corresponding cathode electrodes 223 is electrically connected to the corresponding cathode electrodes 223, and the other side of each of the heating assemblies 24 close to the driving substrate 10 is electrically connected to the driving circuit layer 12, so as to form a heating circuit. This heating circuit is activated at a low temperature to heat the light-emitting units 22.

Please refer to FIG. 2, FIG. 2 is a structural schematic view of a first embodiment of a heating assembly according to the present disclosure. In some embodiments, each of the heating assemblies 24 may include a temperature switch portion 241 and a heating portion 242. The temperature switch portion 241 is arranged between adjacent two light-emitting units 22 and is electrically connected to corresponding cathode electrodes 223 of the adjacent two light-emitting units 22. The heating portion 242 fills one corresponding heating through-hole 212, and a side of the heating portion 242 close to the corresponding temperature switch portion 241 is in contact with the corresponding temperature switch portion 241. In some embodiments, the driving substrate 10 may include heating electrodes 14 electrically connected to the driving circuit layer 12. A side of the heating portion 242 away from the corresponding temperature switch portion 241 is electrically connected to one corresponding heating electrode 14, so as to form the heating circuit and achieve a single connection. This allows the heating assemblies 24 to heat the light-emitting units 22 at a low temperature, raising temperatures of the light-emitting units 22 and reducing the decrease of light-emitting efficiency of the light-emitting units 22 at a low temperature.

When the temperatures of the light-emitting units 22 are lower than the threshold temperature, the temperature switch portion 241 is activated to enable the corresponding heating portion 242 to rise temperature. When the temperatures of the light-emitting units 22 are higher than the threshold temperature, the temperature switch portion 241 is deactivated. That is, when the temperatures of the light-emitting units 22 are lower than the threshold temperature, the temperature switch portion 241 is activated, so that the heating circuit is turned on and the heating portion 242 rises temperature to heat the nearby light-emitting units 22, enabling light-emitting units 22 to rise temperature to solve the problem of low light-emitting efficiency caused by a low temperature. When the temperatures of the light-emitting units 22 are higher than the threshold temperature, the temperature switch portion 241 is deactivated, so that the heating circuit turned off, the heating portion 242 cannot rise temperature to heat the light-emitting units 22, avoiding damaging the light-emitting units 22 caused by an excessive temperature.

The temperature switch portion 241 may be a temperature-sensitive switching device. When the ambient temperature is higher than the threshold temperature, the temperature-sensitive switching device is disactivated to turn off the heating circuit, so that the heating circuit does not perform heating work. When the ambient temperature is lower than the threshold temperature, the temperature-sensitive switching device is activated to turn on the heating circuit, so that the heating portion 242 rise the temperature to heat the light-emitting units 22. Since the temperature switch portion 241 is a temperature-sensitive switching device automatically switching between activated and disactivated states based on temperature, automatic heating may be achieved without an additional temperature sensor, simplifying the structure of the display panel. The activated and disactivated states of the temperature switch portion 241 is not controlled by a control unit to control the heating of the heating assemblies 24, making the control of heating simpler, easier, and easy to implement.

In some embodiments, the material of the temperature switch portion 241 is a Transitional Insulator and Conductor (TIC) material. When the temperature is lower than the threshold temperature, the temperature switch portion 241 is activated. This material may transform into a conductor at a low temperature and may transform into an insulator when the temperature rises. Thus, the temperature switch portion 241 made of TIC material may transform into conductor when the temperatures of the light-emitting units 22 are lower than the threshold temperature, so as to turn on the heating circuit of the heating electrodes 14-the heating portions 242-the temperature switch portions 241-cathode electrodes 223 to heat the light-emitting units 22. The temperature switch portion 241 made of TIC material may transform into an insulator when the temperatures of the light-emitting units 22 are higher than the threshold temperature, i.e., the temperature switch portion is deactivated, so as to turn off the heating circuit of the heating electrode 14-the heating portion 242-the temperature switch portion 241-cathode electrode 223 and stop the heating work.

In some embodiments, the TIC material may be a composite material formed by mixing a liquid metal with a specific viscosity of silica gel material in a certain ratio and allowing them to solidify naturally. The liquid metal particles in the TIC material are surrounded by the silica gel, so that the TIC material is insulated at a room temperature. When exposed to a low temperature, the TIC material transitions from an insulator to a conductor. After the temperature of the TIC material rises, the TIC material returns to an insulating state. This transition between insulating and conductive states may be transitional and repeated without significant structural damage or electrical performance degradation. In some embodiments, the liquid metal may be Gallium-Indium alloy (EGaIn), Gallium-Indium-Tin alloy (EGaInSn), or sodium-potassium alloy, which may increase volume during solidification.

It should be noted that, the TIC material is initially insulated since the liquid metal particles are surrounded and insulated by silica gel. At a low temperature, the conductive liquid metal particles undergo phase change and rapid expansion, while the insulated silica gel contracts, so that the liquid metal particles break through the silica gel membrane and are connected to each other to exhibit conductive properties. When heated, the temperature of the TIC material rises, the silica gel regains elasticity, and the liquid metal particles melt back and transition from solid state into a liquid state, reducing in volume and returning to the state that are surrounded by the silica gel and exhibit insulated properties.

When the temperature switch portion 241 is manufactured, the TIC material film may be patterned by 3D printing to form the temperature switch portion 241. In some embodiments, the threshold temperature, i.e., the state transition temperature of the temperature switch portion 241, may be set by varying the ratio and composition of the liquid metal and silica gel. The threshold temperature ranges from -40°C to 0°C. For example, the transition temperature (the threshold temperature) of the temperature switch portion 241 is set to -25°C, when the temperatures of the light-emitting units 22 adjacent to the temperature switch portion 241 is higher than -25°C, i.e. when the position of the temperature of the temperature switch portion 241 is higher than -25°C, the temperature switch portion 241 transitions into an insulator and is disactivated. When the temperatures of the light-emitting units 22 adjacent to the temperature switch portion 241 is lower than -25°C, i.e., when the position of the temperature of the temperature switch portion 241 is lower than -25°C, the temperature switch portion 241 transitions into a conductor and is activated, so that the heating circuit is turned on to enable the heating portion 242 to heat and rise the temperature.

In some embodiments, the heating portion 242 is made of a metal material or an alloy material with a thermal resistance effect, such as one or more of Platinum (Pt), Copper (Cu), Iron (Fe), Nickel (Ni), or Iron-Nickel alloy (Fe-Ni), which is chosen based on actual needs to satisfy heating requirements like a heating rate and a thermal conductivity.

In this embodiment, the temperature switch portion 241 is arranged in the corresponding heating opening 232, and the heating portion 242 fills the corresponding heating through-hole 212. In some embodiments, each cathode electrode 223 extends to the surface of the pixel definition layer 23 away from the glass substrate 21, is connected to an adjacent cathode electrode 223, and covers one corresponding heating opening 232. The temperature switch portion 241 is arranged in the corresponding heating opening 232 of the pixel definition layer 23, the side of the temperature switch portion 241 close to the corresponding cathode electrode 223 is in contact with the corresponding cathode electrode 223 to form an electrical connection. In some embodiments, the orthographic projection of each of the heating openings 232 on the glass substrate 21 at least partially cover the corresponding heating through-hole 212 to be connected to the corresponding heating through-hole 212. For example, the orthographic projection of each of the heating openings 232 on the glass substrate 21 is fully cover the corresponding heating through-hole 212, so that the temperature switch portion 241 is in contact with the corresponding heating portion 242 to form an electronic connection and increase the contact area, thereby improving a reliable electrical connection. The heating portion 242 fills the corresponding heating through-hole 212, the side of the heating portion 242 close to the corresponding temperature switch portion 241 is in contact with the corresponding temperature switch portion 241, and the side of the heating portion 242 away from the corresponding temperature switch portion 241 is electrically connected to the corresponding heating electrode 14 on the driving substrate 10, so as to form the heating circuit.

In this embodiment, the temperature switch portion 241 is arranged in the corresponding heating opening 232 of the pixel definition layer 23, so that the temperature switch portion 241 is located the surrounding region of the light-emitting layer 222 of the corresponding light-emitting unit 22 to accurately monitor temperature of the corresponding light-emitting layer 222 and enable the state transition temperature of the temperature switch portion 241 to be close to the preset threshold temperature, thereby improving the heating sensitivity of the heating assemblies 24. In addition, the heating portion 242 is arranged in the corresponding heating through-hole 212 of the glass substrate 21 with good thermal conductivity, after a part of the heating portion 242 is heated, the generated thermal energy may be quickly conducted to the surroundings through the glass substrate 21, so as to heat the corresponding light-emitting layer 222. The glass substrate 21 has a thermal stability, that is, the glass substrate 21 may quickly conduct the thermal energy, avoiding the problem of inability to dissipate thermal energy quickly after local temperature rises and causing the temperature switch portion 241 to disactivated again. Due to the larger blank space of the glass substrate 21 compared to the blank space of the film layer where the light-emitting units 22 and the pixel definition layer 23 are located above the glass substrate 21, the glass substrate 21 can meet the volume and area requirements of the heating part 242, thereby improving the heating effect.

In some embodiments, since each of the cathode electrodes 223 is in contact with and electrically connected to the corresponding heating assembly 24, heating driving signals are provided to the heating assemblies 24 through the cathode electrodes 223, that is, the cathode electrodes 223 may serve as one of the heating sources. Due to the direct contact between the cathode electrode 223 and the corresponding light-emitting layer 222, the cathode electrode 223 most directly reflects the actual temperature around the corresponding light-emitting layer 222, thereby making the temperature sensitivity of the corresponding temperature switch portion 241 high, and making the relationship between the heating starting time of the heating assemblies 24 and the temperatures of the light-emitting layers 222 accurate. That is, the time interval between the moment when the temperatures of the light-emitting layers 222 drop to the threshold temperature and the moment when the temperature switches of the heating assemblies 24 are activated is short. In addition, due to the interconnection of the cathode electrodes 223 to form a whole surface design, under the voltage division of local heating voltage, the whole surface design will quickly compensate for the voltage loss and avoid significant impact of local voltage. Moreover, by using the cathode electrodes 223 as one of the heating sources, there is no need to additionally design a layer of electrodes, thereby simplifying the structure, avoiding increasing the process and preventing crosstalk between the electrode signal and signals of other film layers.

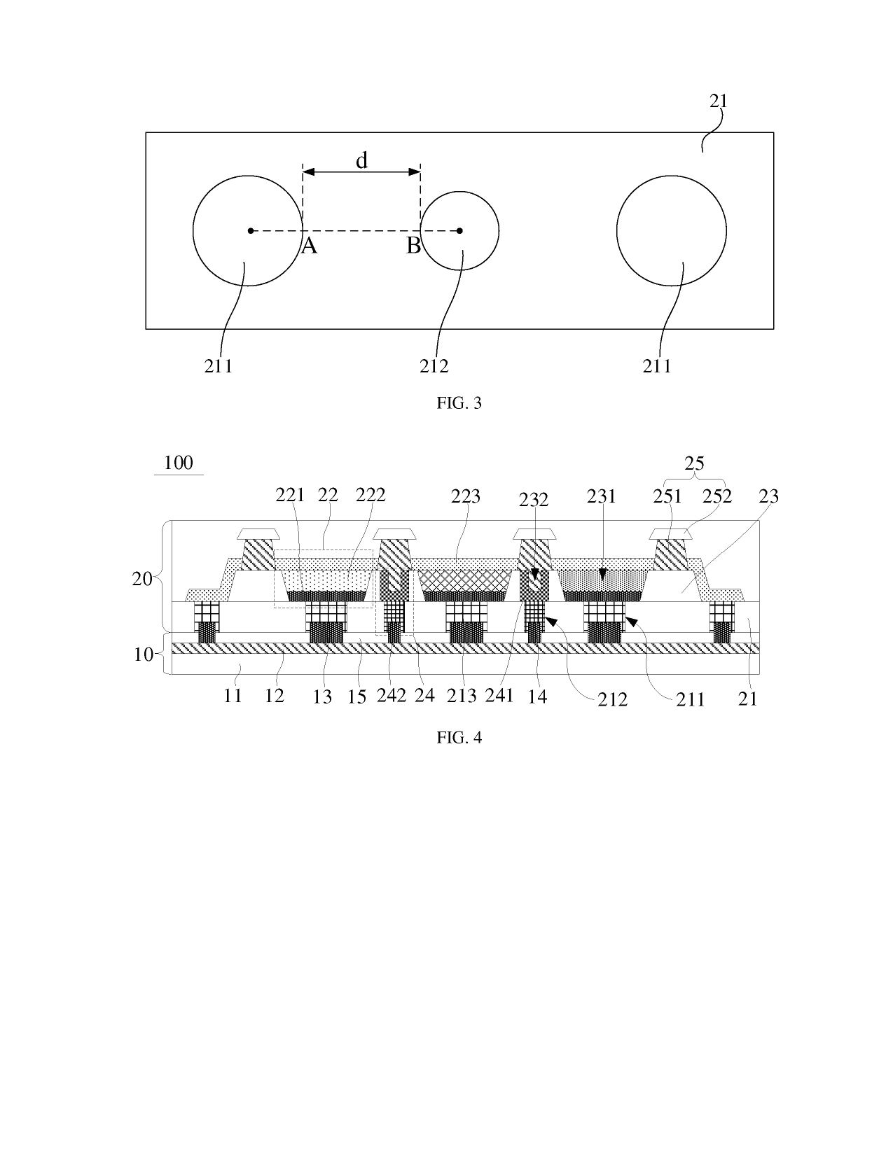

Please refer to FIG. 3, FIG. 3 is a structural schematic view of an electrode through-holes and a heating through-hole according to some embodiments of the present disclosure. In this embodiment, the spacing d between one heating through-hole 212 and one adjacent electrode through-hole 211 is at least greater than 1 µm. It should be noted that the adjacent electrode through-hole 211 refers to the electrode through-hole 211 closest to the heating through-hole 212. The spacing d is defined as: on the line connecting the central axis of the heating through-hole 212 and the central axis of the electrode through-hole 211, the intersection point between the electrode through-hole 211 and the line is A, and the intersection point between the heating through-hole 212 and the line is B. The distance AB between point A and point B is the spacing d between the heating through-hole 212 and the adjacent electrode through-hole 211.

In some embodiments, the diameters of the electrode through-holes 211 and the heating through-holes 212 may be adjusted based on actual needs, provided the spacing d between the heating through-hole 212 and the adjacent electrode through-hole 211 is at least grater than 1 µm. In some embodiments, the diameters of the electrode through-holes 211 and the heating through-holes 212 may be set according to the drilling process. For example, in limited space, the diameter sizes of the electrode through-holes 211 may be prioritized, and the diameter sizes of the heating through-holes 212 may be appropriately reduced, but the diameter sizes of the heating through-holes 212 should also be ensured as large as possible to ensure the heating effect.

Please refer to FIG. 4, FIG. 4 is a structural schematic view of a second embodiment of a display panel according to the present disclosure. In this embodiment, the light-emitting support plate 20 may include conductive isolation structures 25 configured to separate the light-emitting layers 222 of the light-emitting units 22 to achieve a pixel array and prevent pixel crosstalk. The conductive isolation structures 25 may be configured to interconnects the cathode electrodes 223 of light-emitting units 22, thereby achieving a mesh connection between cathode electrodes 223 of different light-emitting units 22 and the uniformity of the overall surface signal of the cathode electrodes 223.

Each of the conductive isolation structure 25 may include a conductive layer 251 and an insulating top portion 252. The conductive layer 251 is arranged on the side of the pixel definition layer 23 away from the glass substrate 21, protrudes from the pixel definition layer 23 and surrounds one corresponding pixel opening 231. The insulating top portion 252 is arranged on the side of one corresponding conductive layer 251 away from the pixel definition layer 23 and covers the corresponding conductive layer 251, and extends beyond the corresponding conductive layer 251 in the direction parallel to the pixel definition layer 23. The cathode electrode 223 extends to one corresponding conductive layer 251 and is in contact with the corresponding conductive layer 251 to form an electrical connection. That is, the part of the top structure extending from one corresponding conductive layer 251 is overhung relative to the corresponding conductive layer 251, so as to form an overhang structure. In the process of vapor deposition of the light-emitting layers 222 and the cathode electrodes 223, due to the presence of the overhang structure, the organic light-emitting layers 222 and the cathode electrodes 223 may form a fault deposition at the bottom of the pixel openings 231. After forming a single light-emitting unit 22 through a single etching, an inorganic encapsulation layer may be configured to encapsulate and protect the monochromatic light-emitting layer 222 and the cathode electrode 223 to form an etching protection layer. Then, other colored organic light-emitting layers 222 and cathode electrodes 223 may be manufactured one by one. After both the three-color organic light-emitting layers 222 and the cathode electrodes 223 are patterned, an organic encapsulation layer and an inorganic encapsulation layer may be configured for overall encapsulation. When the light-emitting layers 222 and the cathode electrodes 223 are performed vapor deposition, the edge range of each film layer in the light-emitting layers 222 may be adjusted by adjusting the vapor deposition angle. There are a plurality of conductive isolation structures 25, and adjacent two conductive isolation structures 25 share a same side of the adjacent conductive isolation structures 25. That is, the sides of adjacent two conductive isolation structures 25 that are close to each other share a same side to ensure that the spacing d between light-emitting units 22 is equal, which is beneficial for display uniformity and increase of pixel opening rate. In some embodiments, the conductive isolation structure 25 is a ring-shaped structure that matches the shape of the corresponding light-emitting unit 22, so as to manufacture the corresponding light-emitting unit 22 in a preset shape.

In the direction perpendicular to the light-emitting support plate 20, the longitudinal cross-section of the sidewall of the conductive layer 251 may be trapezoidal, and the horizontal cross-section of the sidewall of the conductive isolation structure in the direction parallel to the light-emitting support plate 20 gradually decreases in the direction close the insulating top portion 252, so as to facilitate the contact between the cathode electrodes 223 and the conductive layers 251.

The conductive layer 251 may be made of metal or conductive oxide materials. the metal material may include Copper (Cu), Aluminum (Al), Silver (Ag), Gold (Au), or other metal materials or the alloys thereof with high conductivity. The conductive oxide material may include Indium Tin Oxide (ITO), Indium Zinc Oxide (IZO), Indium Gallium Zinc Oxide (IGZO), or other metallic oxide material with high conductivity. The conductive oxide film layer may coat the surface of the metal film layer to form a passivation protection layer to protect the metal film layer.

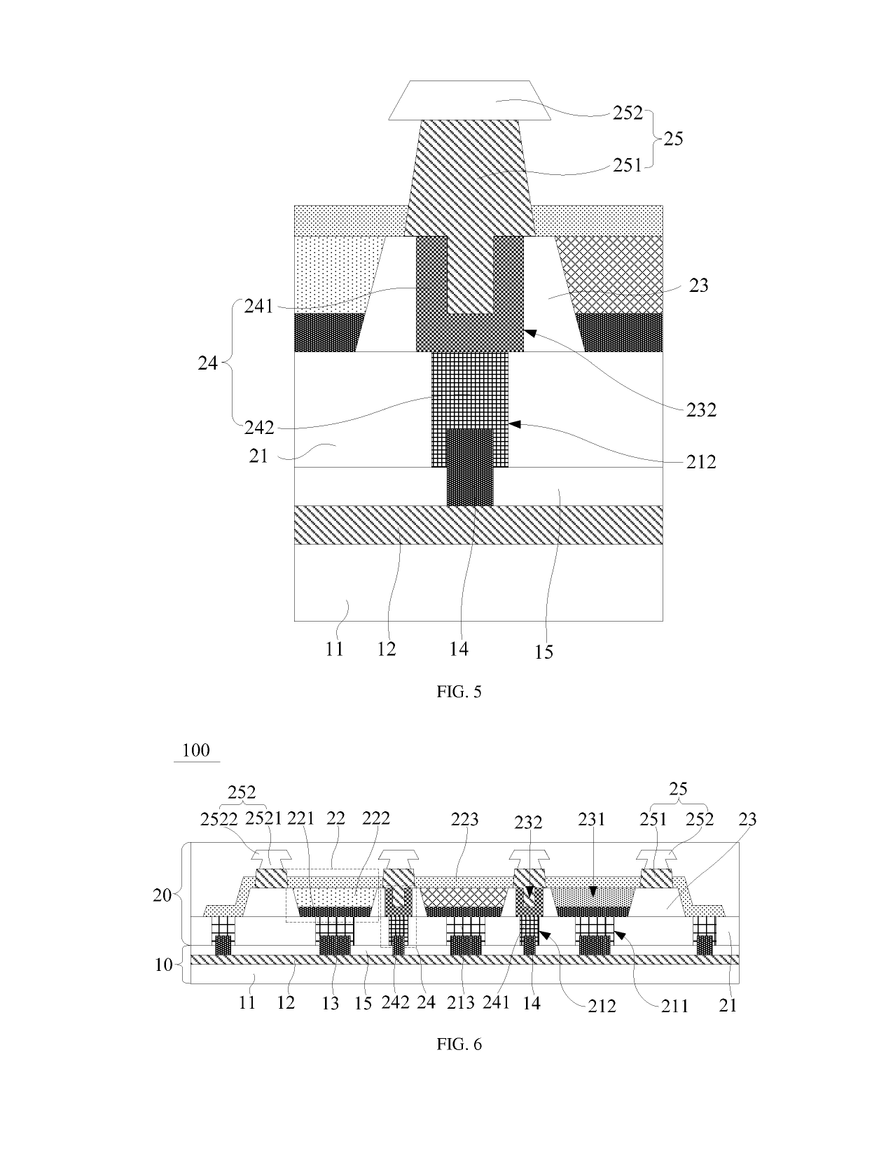

Please refer to FIG. 5, FIG. 5 is a structural schematic view of a second embodiment of a heating assembly according to the present disclosure. In some embodiments, the orthographic projection of the conductive layer 251 on the glass substrate 21 covers the orthographic projection of the corresponding heating opening 232 on the glass substrate 21. The temperature switch portion 241 is arranged in the corresponding heating opening 232, a side of the temperature switch portion 241 close to the corresponding conductive layer 251 is in contact with the corresponding conductive layer 251 to electrically connected to the corresponding cathode electrode 223 through the conductive layer 251. In some embodiments, during manufacture, the TIC material is first coated in the heating opening 232 to form the corresponding temperature switch portion 241. Then the conductive layer 251 is manufactured and covers the corresponding heating opening 232 to form an electrical connection with the corresponding temperature switch portion 241. Therefore, after the cathode electrode 223 is performed vapor deposition, the temperature switch portion 241 is electrically connected to the corresponding cathode electrode 223 through the corresponding conductive layer 251.

In this embodiment, by configuring the conductive isolation structure 25 for the manufacture of the corresponding patterned light-emitting unit 22, the Fine Metal Mask (FMM) vapor deposition process may be effectively replaced, achieving high resolution and colorization of passive matrix OLEDs, and better solving the problems of low resolution and low device yield of cathode electrode mask. Furthermore, by making the side of the temperature switch portion 241 close to the corresponding conductive layer 251 in contact with the corresponding conductive layer 251, an electrical connection is formed between the temperature switch portion 241 and the corresponding cathode electrode 223 through the conductive layer 251, so that a heating driving signal may be provided to the heating assembly 24 through the corresponding cathode electrode 223 to form the above-mentioned heating circuit, achieving the automatic heating function of the corresponding light-emitting unit 22 at a low temperature.

Please refer to FIG. 6, FIG. 6 is a structural schematic view of a third embodiment of a display panel according to the present disclosure. In this embodiment, a part of the conductive layer 251 close to the corresponding heating opening 232 extends into the corresponding heating opening 232 to be in contact with the corresponding temperature switch portion 241 and form an electrical connection. That is, the deposition thickness of the film layer of the temperature switch portion 241 is lower than the depth of the corresponding heating opening 232, and the lower part of the conductive layer 251 extends into the corresponding heating opening to be electrically connected to the film layer of the corresponding temperature switch portion 241. This arrangement method may improve the reliability of the connection between the conductive layer 251 and the corresponding temperature switch portion 241, and increase the contact area between the conductive layer 251 and the corresponding temperature switch portion 241. This arrangement method can not only improve the conductivity between the conductive layer 251 and the corresponding cathode electrode 223, but also increase the temperature sensing area of the temperature switch portion 241 to further enhance the temperature sensitivity of the temperature switch portion 241 and improve the heating effect of the corresponding heating assembly 24.

In this embodiment, the insulating top portion 252 may include a base portion 2521 and an overhang top portion 2522 that are integrated with each other. The base portion 2521 is arranged on the corresponding conductive layer 251 away from the glass substrate 21, protrudes from the conductive layer 251 and surrounds one corresponding pixel opening 231. The overhang top portion 2522 covers the surface of the corresponding base portion 2521 away from the conductive layer 251 and extends beyond the corresponding base portion 2521 in the direction parallel to the glass substrate 21, the portion extending beyond the base portion 2521 is overhung to form a overhang structure, that is, the insulating top portion 252 is in a "T" shape. In some embodiments, the orthographic projection of the base portion 2521 on the corresponding conductive layer 251 does not exceed the corresponding conductive layer 251 to improve the opening ratio and facilitate the contact between the cathode electrode 223 and the corresponding conductive layer 251. The insulation top portion 252 may be made of materials including SiO2, SiNx, and SiNO. Different materials have different etching rates to achieve a "T" shape appearance.

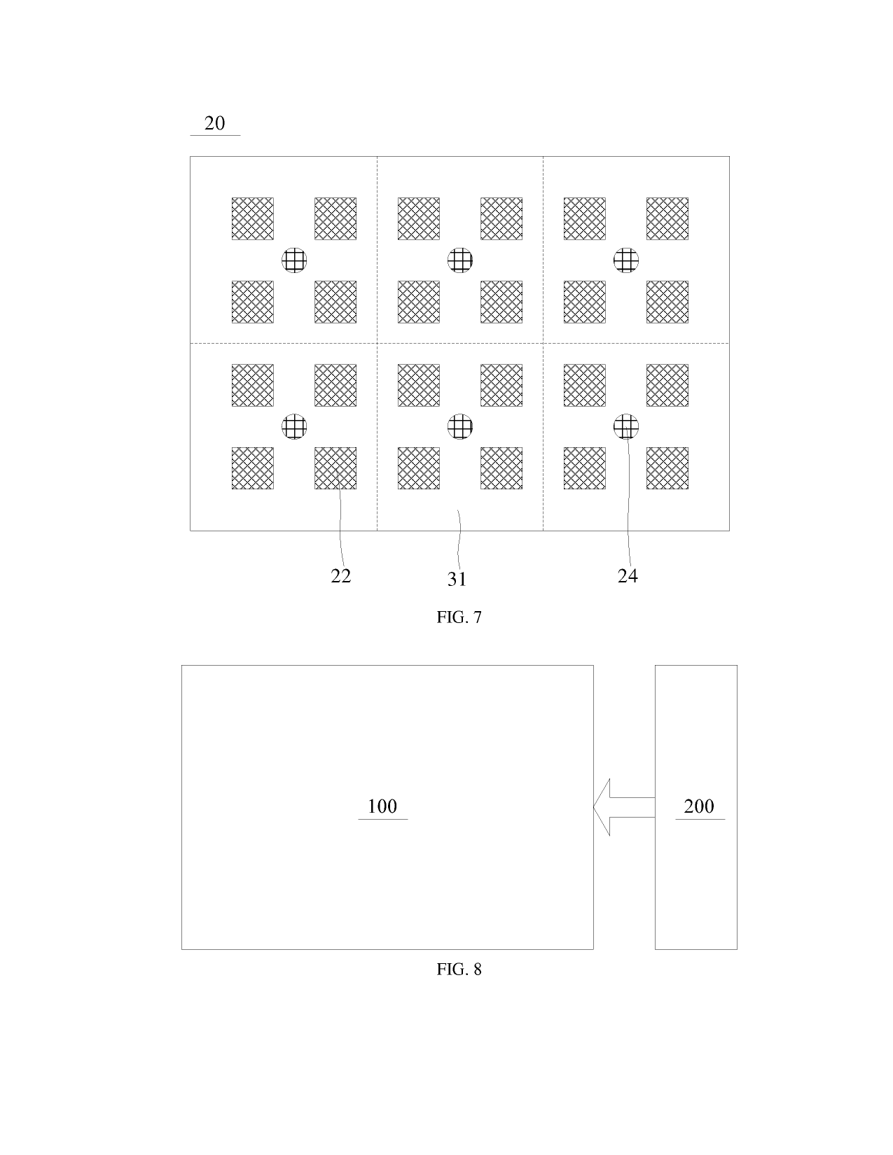

Please refer to FIG. 7, FIG. 7 is a planar distribution schematic view of heating assemblies according to some embodiments of the present disclosure. In this embodiment, the light-emitting support plate 20 is divided into a plurality of interconnected heating regions 31. Each heating region 31 may include at least two light-emitting units 22 and at least one heating assembly 24 distributed uniformly within the heating region 31.

It should be understood that there is no need to define the corresponding heating opening 232 and arrange the corresponding heating assembly 24 in the pixel definition layer 23 below each conductive layer 251. The light-emitting support plate 20 may be divided into a plurality of heating regions 31, and each of the heating regions 31 may include m rows and n columns of light-emitting units 22, that is, each heating region 31 may have m × n light-emitting units 22, where m and n are both positive integers, and m × n is a positive integer greater than or equal to 2. At least one heating assembly 24 may be arranged in each heating region 31 to heat the light-emitting units 22 in the corresponding heating region 31. For example, each heating region 31 has 2 × 2 light emitting units 22 and one heating assembly 24 arranged at the center position of the corresponding heating region 31. The distance between the heating assembly 24 and the center point of each of the four corresponding light emitting units 22 is equal, so that the heating effect of the heating assembly 24 on each light emitting unit 22 is balanced. In another example, each heating region 31 have m × n light-emitting units 22, where m and n are greater than or equal to 3. Several (at least two) heating assemblies 24 are arranged in each heating region 31, and the heating assemblies 24 are evenly distributed in each heating region 31 to ensure the heating rate and heating balance of the light-emitting units 22.

Please refer to FIG. 8, FIG. 8 is a structural schematic view of a display apparatus according to some embodiments of the present disclosure. In this embodiment, a display apparatus is provided and may be applied to tablets, phones, vehicles, VR glasses, lighting devices, and other display fields.

The display apparatus may include a display panel 100 and a control circuit board 200. The control circuit board 200 is electrically connected to the display panel 100, and is configured to provide various driving signals, power signals, and other driving signals required by the display panel 100 to the display panel, thereby controlling the display panel 100 to display corresponding images. The structure and function of the display panel 100 are the same or similar to those of the display panel 100 in the previous embodiments, and may achieve the same technical effects. For details, please refer to the relevant introduction mentioned above.

This display apparatus may be suitable for a low-temperature environment, and may automatically heat the light-emitting units 22 to solve the problem of low light-emitting efficiency of the light-emitting units 22 caused by a low temperature, and effectively solve the problem of the brightness reduction and display abnormality of the display panel 100 at a low temperature.

The above are only some embodiments of the present disclosure, and do not limit the scope of the present disclosure. Any equivalent structural or process transformations made using the content of the specification and drawings of the present disclosure, or direct or indirect applications in other related technical fields, fall within the scope of the present disclosure.

1. A display panel, comprising:
a driving substrate, comprising a driving circuit layer and a plurality of driving electrodes electrically connected to the driving circuit layer; and
a light-emitting support plate, comprising:
a glass substrate, arranged on the driving substrate and having a plurality of electrode through-holes, and each of the plurality of electrode through-holes corresponding to one corresponding driving electrode of the plurality of driving electrodes; and
light-emitting units, arranged in an array and on a side of the glass substrate away from the driving substrate, each of the light-emitting units being electrically connected to one corresponding driving electrode of the plurality of driving electrodes through one corresponding electrode through-hole of the plurality of electrode through-holes;
wherein the light-emitting support plate comprises heating assemblies, and each of the heating assemblies is arranged between adjacent two light-emitting units of the light-emitting units; the glass substrate defines heating through-holes, and each of the heating assemblies is electrically connected to the driving circuit layer through one corresponding heating through-hole of the heating through-holes;
when temperatures of the light-emitting units are lower than a threshold temperature, the heating assemblies are activated to heat the light-emitting units.

2. The display panel according to claim 1, wherein the heating assemblies comprise temperature switch portions and heating portions, and each of the heating assemblies comprises one corresponding temperature switch portion of the temperature switch portions and one corresponding heating portion of the heating portions, each of the heating through-holes is located between adjacent two electrode through-holes of the plurality of electrode through-holes, the driving substrate comprises heating electrodes electrically connected to the driving circuit layer;
the light-emitting units comprise cathode electrodes, and each of the light-emitting units comprises one corresponding cathode electrode of the cathode electrodes; each of the temperature switch portions is arranged between adjacent two light-emitting units of the light-emitting units and is electrically connected to corresponding cathode electrodes of the adjacent two light-emitting units; each of the heating portions fills one corresponding heating through-hole of the heating through-holes, a side of each of the heating portions close to one corresponding temperature switch portion is in contact with the corresponding temperature switch portion, and another side of each of the heating portions away from the corresponding temperature switch portion is electrically connected to one corresponding heating electrode of the heating electrodes;
when the temperatures of the light-emitting units are lower than the threshold temperature, the temperature switch portions are activated to heat the heating portions; when the temperatures of the light-emitting units are higher than the threshold temperature, the temperature switch portions are deactivated.

3. The display panel according to claim 2, wherein a material of each of the temperature switch portions is a transitional conductor and insulator material; when temperatures of the temperature switch portions are lower than the threshold temperature, the temperature switch portions transform into conductors and are activated to enable the heating portions to rise temperatures of the heating portions; when the temperature of the temperature switch portions are higher than the threshold temperature, the temperature switch portions transform into insulators and are deactivated; a material of each of the heating portions is a metal material or an alloy material with a thermal resistance effect.

4. The display panel according to claim 2, wherein the light-emitting support plate comprises a pixel definition layer arranged on the glass substrate, the pixel definition layer defines a plurality of pixel openings, and each of the plurality of pixel openings corresponds to one corresponding light-emitting unit of the light-emitting units; along a direction of the glass substrate away from the driving substrate, each of the plurality of pixel openings is sequentially stacked with an anode electrode, a light-emitting layer, and a cathode electrode of the cathode electrodes to form the corresponding light-emitting unit;
the pixel definition layer comprises heating openings, each of the heating openings is located between adjacent two pixel openings of the plurality of pixel openings; each of the temperature switch portions is arranged in one corresponding heating opening of the heating openings, and a side of each of the temperature switch portions close to the corresponding cathode electrodes is electrically connected to the corresponding cathode electrodes; a projection of each of the heating openings on the glass substrate at least partially covers one corresponding heating through-hole of the heating through-holes, so that a side of each of the heating portions close to the corresponding temperature switch portion is in contact with the corresponding temperature switch portion.

5. The display panel according to claim 4, wherein each of the cathode electrodes extends to a surface of the pixel definition layer away from the glass substrate and is connected to one adjacent cathode electrode of the cathode electrodes; a side of each of the temperature switch portions close to the corresponding cathode electrodes is electrically connected to the corresponding cathode electrodes.

6. The display panel according to claim 4, wherein the light-emitting support plate comprises conductive isolation structures, the conductive isolation structures comprise conductive layers and insulating top portions, and each of the conductive isolation structures comprises one corresponding conductive layer of the conductive layers and one corresponding insulating top portion of the insulating top portions; each of the conductive layers is arranged on a side of the pixel definition layer away from the glass substrate and surrounds one corresponding pixel opening of the plurality of pixel openings; each of the insulating top portions is arranged on a surface of one corresponding conductive layer of the conductive layers away from the pixel definition layer, covers the corresponding conductive layer, and extends beyond the corresponding conductive layer in a direction parallel to the pixel definition layer; each of the cathode electrodes extends to one corresponding conductive layer of the conductive layers and is in contact with the corresponding conductive layer to form an electrical connection;
an orthographic projection of each of the conductive layers on the glass substrate covers an orthographic projection of one corresponding heating opening of the heating openings on the glass substrate; a side of each of the temperature switch portions close to one corresponding conductive layer of the conductive layers is contact with the corresponding conductive layer to electrically connected to the corresponding cathode electrodes.

7. The display panel according to claim 6, wherein a side of each of the conductive layers close to one corresponding heating opening of the heating openings partially extends into the corresponding heating opening to be in contact with the corresponding temperature switch portion and form an electrical connection.

8. The display panel according to claim 1, wherein the light-emitting support plate is divided into a plurality of heating regions connected to each other, each of the heating regions comprises at least two light-emitting units and at least one heating assembly uniformly distributed.

9. The display panel according to claim 1, wherein a spacing between each of the heating through-holes and an adjacent electrode through-hole of the plurality of electrode through-holes is at least greater than 1 µm; the threshold temperature ranges from -40°C to 0°C.

10. A display apparatus, comprising:
a display panel; and
a control circuit board, electrically connected to the display panel and configured to control the display panel to display a corresponding image;
the display panel comprising:
a driving substrate, comprising a driving circuit layer and a plurality of driving electrodes electrically connected to the driving circuit layer; and
a light-emitting support plate, comprising:
a glass substrate, arranged on the driving substrate and having a plurality of electrode through-holes, and each of the plurality of electrode through-holes corresponding to one corresponding driving electrode of the plurality of driving electrodes; and
light-emitting units, arranged in an array and on a side of the glass substrate away from the driving substrate, each of the light-emitting units being electrically connected to one corresponding driving electrode of the plurality of driving electrodes through one corresponding electrode through-hole of the plurality of electrode through-holes;
wherein the light-emitting support plate comprises heating assemblies, and each of the heating assemblies is arranged between adjacent two light-emitting units of the light-emitting units; the glass substrate defines heating through-holes, and each of the heating assemblies is electrically connected to the driving circuit layer through one corresponding heating through-hole of the heating through-holes;
when temperatures of the light-emitting units are lower than a threshold temperature, the heating assemblies are activated to heat the light-emitting units.

11. The display apparatus according to claim 10, wherein the heating assemblies comprise temperature switch portions and heating portions, and each of the heating assemblies comprises one corresponding temperature switch portion of the temperature switch portions and one corresponding heating portion of the heating portions, each of the heating through-holes is located between adjacent two electrode through-holes of the plurality of electrode through-holes, the driving substrate comprises heating electrodes electrically connected to the driving circuit layer;
the light-emitting units comprise cathode electrodes, and each of the light-emitting units comprises one corresponding cathode electrode of the cathode electrodes; each of the temperature switch portions is arranged between adjacent two light-emitting units of the light-emitting units and is electrically connected to corresponding cathode electrodes of the adjacent two light-emitting units; each of the heating portions fills one corresponding heating through-hole of the heating through-holes, a side of each of the heating portions close to one corresponding temperature switch portion is in contact with the corresponding temperature switch portion, and another side of each of the heating portions away from the corresponding temperature switch portion is electrically connected to one corresponding heating electrode of the heating electrodes;
when the temperatures of the light-emitting units are lower than the threshold temperature, the temperature switch portions are activated to heat the heating portions; when the temperatures of the light-emitting units are higher than the threshold temperature, the temperature switch portions are deactivated.

12. The display apparatus according to claim 11, wherein a material of each of the temperature switch portions is a transitional conductor and insulator material; when temperatures of the temperature switch portions are lower than the threshold temperature, the temperature switch portions transform into conductors and are activated to enable the heating portions to rise temperatures of the heating portions; when the temperature of the temperature switch portions are higher than the threshold temperature, the temperature switch portions transform into insulators and are deactivated; a material of each of the heating portions is a metal material or an alloy material with a thermal resistance effect.

13. The display apparatus according to claim 11, wherein the light-emitting support plate comprises a pixel definition layer arranged on the glass substrate, the pixel definition layer defines a plurality of pixel openings, and each of the plurality of pixel openings corresponds to one corresponding light-emitting unit of the light-emitting units; along a direction of the glass substrate away from the driving substrate, each of the plurality of pixel openings is sequentially stacked with an anode electrode, a light-emitting layer, and a cathode electrode of the cathode electrodes to form the corresponding light-emitting unit;
the pixel definition layer comprises heating openings, each of the heating openings is located between adjacent two pixel openings of the plurality of pixel openings; each of the temperature switch portions is arranged in one corresponding heating opening of the heating openings, and a side of each of the temperature switch portions close to the corresponding cathode electrodes is electrically connected to the corresponding cathode electrodes; a projection of each of the heating openings on the glass substrate at least partially covers one corresponding heating through-hole of the heating through-holes, so that a side of each of the heating portions close to the corresponding temperature switch portion is in contact with the corresponding temperature switch portion.

14. The display apparatus according to claim 13, wherein each of the cathode electrodes extends to a surface of the pixel definition layer away from the glass substrate and is connected to one adjacent cathode electrode of the cathode electrodes; a side of each of the temperature switch portions close to the corresponding cathode electrodes is electrically connected to the corresponding cathode electrodes.

15. The display apparatus according to claim 13, wherein the light-emitting support plate comprises conductive isolation structures, the conductive isolation structures comprise conductive layers and insulating top portions, and each of the conductive isolation structures comprises one corresponding conductive layer of the conductive layers and one corresponding insulating top portion of the insulating top portions; each of the conductive layers is arranged on a side of the pixel definition layer away from the glass substrate and surrounds one corresponding pixel opening of the plurality of pixel openings; each of the insulating top portions is arranged on a surface of one corresponding conductive layer of the conductive layers away from the pixel definition layer, covers the corresponding conductive layer, and extends beyond the corresponding conductive layer in a direction parallel to the pixel definition layer; each of the cathode electrodes extends to one corresponding conductive layer of the conductive layers and is in contact with the corresponding conductive layer to form an electrical connection;
an orthographic projection of each of the conductive layers on the glass substrate covers an orthographic projection of one corresponding heating opening of the heating openings on the glass substrate; a side of each of the temperature switch portions close to one corresponding conductive layer of the conductive layers is contact with the corresponding conductive layer to electrically connected to the corresponding cathode electrodes.

16. The display apparatus according to claim 15, wherein a side of each of the conductive layers close to one corresponding heating opening of the heating openings partially extends into the corresponding heating opening to be in contact with the corresponding temperature switch portion and form an electrical connection.

17. The display apparatus according to claim 10, wherein the light-emitting support plate is divided into a plurality of heating regions connected to each other, each of the heating regions comprises at least two light-emitting units and at least one heating assembly uniformly distributed.

18. The display apparatus according to claim 10, wherein a spacing between each of the heating through-holes and an adjacent electrode through-hole of the plurality of electrode through-holes is at least greater than 1 µm; the threshold temperature ranges from -40°C to 0°C.

19. A display panel, comprising:
a driving substrate, comprising a driving circuit layer and a plurality of driving electrodes electrically connected to the driving circuit layer; and
a light-emitting support plate, comprising:
a plurality of electrode through-holes, and each of the plurality of electrode through-holes corresponding to one corresponding driving electrode of the plurality of driving electrodes; and
light-emitting units, arranged in an array and on a side of the light-emitting support plate, each of the light-emitting units being electrically connected to one corresponding driving electrode of the plurality of driving electrodes through one corresponding electrode through-hole of the plurality of electrode through-holes;
wherein the light-emitting support plate comprises heating assemblies, and each of the heating assemblies is arranged between adjacent two light-emitting units of the light-emitting units; the light-emitting support plate defines heating through-holes, and each of the heating assemblies is electrically connected to the driving circuit layer through one corresponding heating through-hole of the heating through-holes;
when temperatures of the light-emitting units are lower than a threshold temperature, the heating assemblies are activated to heat the light-emitting units.

20. The display panel according to claim 19, wherein the heating assemblies comprise temperature switch portions and heating portions, and each of the heating assemblies comprises one corresponding temperature switch portion of the temperature switch portions and one corresponding heating portion of the heating portions, each of the heating through-holes is located between adjacent two electrode through-holes of the plurality of electrode through-holes, the driving substrate comprises heating electrodes electrically connected to the driving circuit layer;
the light-emitting units comprise cathode electrodes, and each of the light-emitting units comprises one corresponding cathode electrode of the cathode electrodes; each of the temperature switch portions is arranged between adjacent two light-emitting units of the light-emitting units and is electrically connected to corresponding cathode electrodes of the adjacent two light-emitting units; each of the heating portions fills one corresponding heating through-hole of the heating through-holes, a side of each of the heating portions close to one corresponding temperature switch portion is in contact with the corresponding temperature switch portion, and another side of each of the heating portions away from the corresponding temperature switch portion is electrically connected to one corresponding heating electrode of the heating electrodes;
when the temperatures of the light-emitting units are lower than the threshold temperature, the temperature switch portions are activated to heat the heating portions; when the temperatures of the light-emitting units are higher than the threshold temperature, the temperature switch portions are deactivated.
